(19) United States
(12) Patent Application Publication
(10) Pub. No.: US 2022/0406809 A1
(43) Pub. Date: Dec. 22, 2022

(54) SEMICONDUCTOR MEMORY DEVICE

(71) Applicant: Kioxia Corporation, Tokyo (JP)

(72) Inventors: Akira TAKASHIMA, Tokyo (JP); Tsunehiro INO, Tokyo (JP)

(73) Assignee: Kioxia Corporation, Tokyo (JP)

(21) Appl. No.: 17/645,138

(22) Filed: Dec. 20, 2021

(30) Foreign Application Priority Data
Jun. 18, 2021 (JP) 2021-101446

(51) Int. Cl. H01L 27/11578; H01L 27/11551

(52) U.S. Cl. CPC H01L 27/11578; H01L 27/11551

(57) ABSTRACT

A semiconductor memory device according to an embodiment includes: a semiconductor layer extending in a first direction; a first gate electrode layer; a charge storage layer between the semiconductor layer and the first gate electrode layer, the charge storage layer containing a first element, a second element, and oxygen, the first element being at least one element selected from the group consisting of hafnium and zirconium, and the second element being at least one element selected from the group consisting of nitrogen and aluminum; a first insulating layer between the charge storage layer and the first gate electrode layer; and a second insulating layer between the semiconductor layer and the first gate electrode layer, the second insulating layer containing silicon and nitrogen, the second insulating layer surrounding the charge storage layer in a cross section that being parallel to the first direction and including the charge storage layer.

### CROSS-REFERENCE TO RELATED APPLICATION

This application is based upon and claims the benefit of priority from Japanese Patent Application No. 2021-101446, filed on Jun. 18, 2021, the entire contents of which are incorporated herein by reference.

### FIELD

Embodiments described herein relate generally to a semiconductor memory device.

### BACKGROUND

A three-dimensional NAND flash memory in which memory cells are three-dimensionally disposed realizes a high degree of integration and a low cost. A memory cell of the three-dimensional NAND flash memory includes a charge storage layer for retention of charges. The three-dimensional NAND flash memory is required to have an excellent charge retention characteristic.

### BRIEF DESCRIPTION OF THE DRAWINGS

FIG. 1 is a block diagram of a semiconductor memory device according to an embodiment;

FIG. 2 is an equivalent circuit diagram of a memory cell array of the semiconductor memory device according to the embodiment;

FIG. 3 is a schematic cross-sectional view of a part of the memory cell array of the semiconductor memory device according to the embodiment;

FIG. 4 is a schematic cross-sectional view of a part of the memory cell array of the semiconductor memory device according to the embodiment;

FIG. 5 is an enlarged schematic cross-sectional view of a part of the memory cell array of the semiconductor memory device according to the embodiment;

FIG. 6 is a schematic cross-sectional view illustrating a method for manufacturing the semiconductor memory device according to the embodiment;

FIG. 7 is a schematic cross-sectional view illustrating the method for manufacturing the semiconductor memory device according to the embodiment;

FIG. 8 is a schematic cross-sectional view illustrating the method for manufacturing the semiconductor memory device according to the embodiment;

FIG. 9 is a schematic cross-sectional view illustrating the method for manufacturing the semiconductor memory device according to the embodiment;

FIG. 10 is a schematic cross-sectional view illustrating the method for manufacturing the semiconductor memory device according to the embodiment;

FIG. 11 is a schematic cross-sectional view illustrating the method for manufacturing the semiconductor memory device according to the embodiment;

FIG. 12 is a schematic cross-sectional view illustrating the method for manufacturing the semiconductor memory device according to the embodiment;

FIG. 13 is a schematic cross-sectional view illustrating the method for manufacturing the semiconductor memory device according to the embodiment;

FIG. 14 is a schematic cross-sectional view illustrating the method for manufacturing the semiconductor memory device according to the embodiment;

FIG. 15 is a schematic cross-sectional view illustrating the method for manufacturing the semiconductor memory device according to the embodiment;

FIG. 16 is a schematic cross-sectional view illustrating the method for manufacturing the semiconductor memory device according to the embodiment;

FIG. 17 is a schematic cross-sectional view illustrating the method for manufacturing the semiconductor memory device according to the embodiment;

FIG. 18 is a schematic cross-sectional view illustrating the method for manufacturing the semiconductor memory device according to the embodiment;

FIG. 19 is a schematic cross-sectional view illustrating the method for manufacturing the semiconductor memory device according to the embodiment;

FIG. 20 is a schematic cross-sectional view illustrating the method for manufacturing the semiconductor memory device according to the embodiment; and

FIG. 21 is a schematic cross-sectional view illustrating the method for manufacturing the semiconductor memory device according to the embodiment.

### DETAILED DESCRIPTION

A semiconductor memory device according to an embodiment includes: a semiconductor layer extending in a first direction; a first gate electrode layer; a charge storage layer provided between the semiconductor layer and the first gate electrode layer, the charge storage layer containing a first element, a second element, and oxygen (O), the first element being at least one element selected from the group consisting of hafnium (Hf) and zirconium (Zr), and the second element being at least one element selected from the group consisting of nitrogen (N) and aluminum (Al); a first insulating layer provided between the charge storage layer and the first gate electrode layer; and a second insulating layer provided between the semiconductor layer and the first gate electrode layer, the second insulating layer containing silicon (Si) and nitrogen (N), the second insulating layer surrounding the charge storage layer in a cross section, and the cross section being parallel to the first direction and including the charge storage layer.

Hereinafter, embodiments will be described with reference to the drawings. In the following description, the same or similar members and the like are denoted by the same reference signs, and a description of the members and the like once described is appropriately omitted.

In the present specification, the term “upper” or “lower” may be used for convenience. The term “upper” or “lower” is merely a term indicating a relative positional relationship in the drawings, and is not a term defining a positional relationship with respect to gravity.

For qualitative analysis and quantitative analysis of a chemical composition of a member included in the semiconductor memory device in the present specification, for example, secondary ion mass spectroscopy (SIMS), energy dispersive X-ray spectroscopy (EDX), or electron energy loss spectroscopy (EELS) can be used. In addition, for example, a transmission electron microscope (TEM) can be used to measure a thickness of the member included in the semiconductor memory device, a distance between the members, and the like. For example, the TEM, X-ray diffraction (XRD), electron beam diffraction (EBD), X-ray photoelectron spectroscopy (XPS), or a synchrotron radiation X-ray absorption fine structure (XAFS) may be used for identification of a constituent substance of the member included in the semiconductor memory device and comparison of a proportion of the constituent substance.

A semiconductor memory device according to an embodiment includes: a semiconductor layer extending in a first direction; a first gate electrode layer; a charge storage layer provided between the semiconductor layer and the first gate electrode layer, the charge storage layer containing a first element, a second element, and oxygen (O), the first element being at least one element selected from the group consisting of hafnium (Hf) and zirconium (Zr), and the second element being at least one element selected from the group consisting of nitrogen (N) and aluminum (Al); a first insulating layer provided between the charge storage layer and the first gate electrode layer; and a second insulating layer provided between the semiconductor layer and the first gate electrode layer, the second insulating layer containing silicon (Si) and nitrogen (N), the second insulating layer surrounding the charge storage layer in a cross section, and the cross section being parallel to the first direction and including the charge storage layer.

The semiconductor memory device according to the embodiment is a three-dimensional NAND flash memory 100.

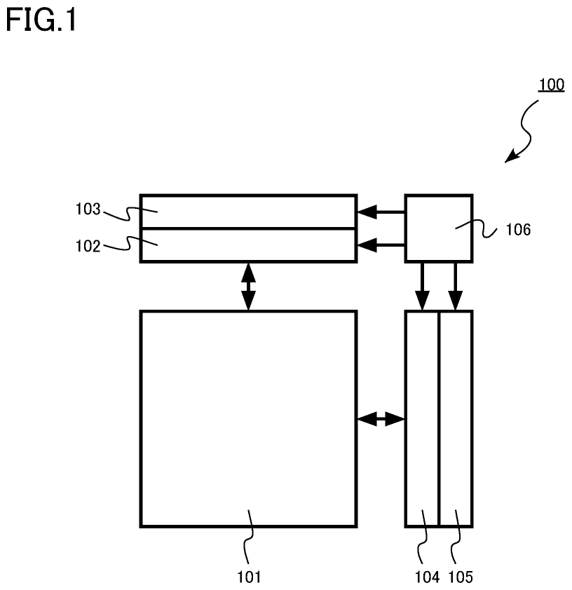

FIG. 1 is a block diagram of the semiconductor memory device according to the embodiment. FIG. 1 illustrates a circuit configuration of the three-dimensional NAND flash memory 100 according to the embodiment. As illustrated in FIG. 1, the three-dimensional NAND flash memory 100 includes a memory cell array 101, a word line driver circuit 102, a row decoder circuit 103, a sense amplifier circuit 104, a column decoder circuit 105, and a control circuit 106.

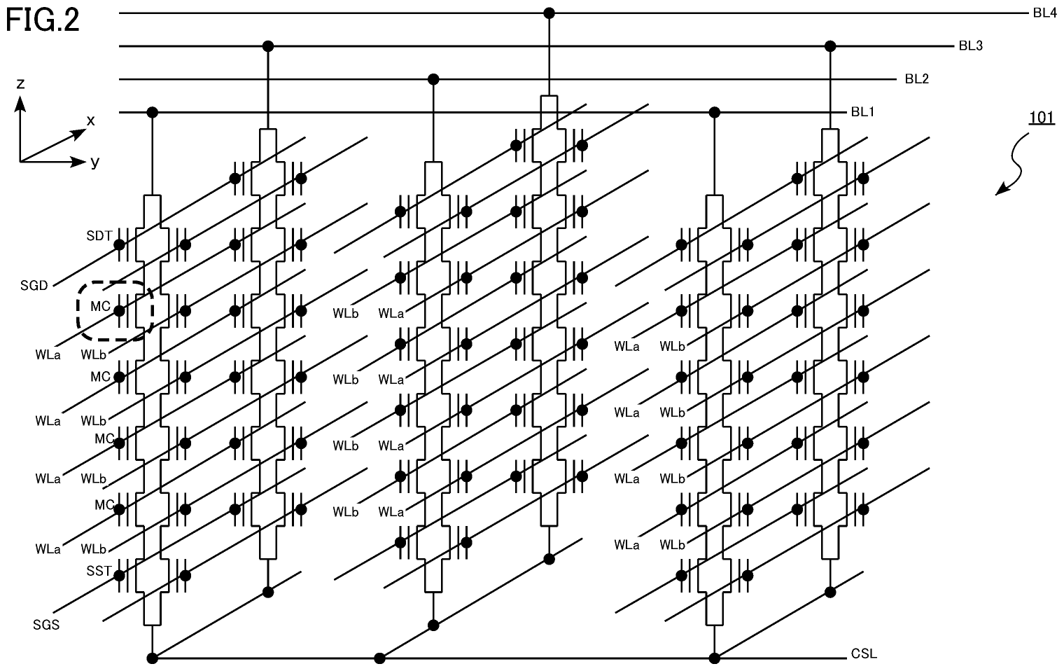

FIG. 2 is an equivalent circuit diagram of a memory cell array of the semiconductor memory device according to the embodiment. FIG. 2 schematically illustrates a wiring structure in the memory cell array 101. The memory cell array 101 according to the embodiment has a three-dimensional structure in which a plurality of memory cells MC are three-dimensionally disposed.

Hereinafter, a z direction illustrated in FIG. 2 is an example of the first direction. An x direction is an example of a second direction. A y direction is an example of a third direction. The x direction intersects the z direction. The y direction intersects the x direction and the z direction. For example, the x direction is orthogonal to the z direction. For example, the y direction is orthogonal to the x direction and the z direction. Note that a direction opposite to the z direction is also regarded as the first direction. A direction opposite to the x direction is also regarded as the second direction. A direction opposite to the y direction is also regarded as the third direction.

As illustrated in FIG. 2, the memory cell array 101 includes the plurality of memory cells MC, a source selection transistor SST, a drain selection transistor SDT, a plurality of word lines WLa and WLb, a plurality of bit lines BL1 to BL4, a common source line CSL, a source selection gate line SGS, and a plurality of drain selection gate lines SGD.

The plurality of memory cells MC are connected in series in the z direction. The plurality of memory cells MC are connected between the source selection transistor SST and the drain selection transistor SDT.

The memory cell MC stores data corresponding to the amount of charge accumulated in the charge storage layer. A threshold voltage of a transistor of the memory cell MC changes according to the amount of charge accumulated in the charge storage layer. When the threshold voltage of the transistor changes, an on-current of the transistor changes. For example, in a case where a state in which the threshold voltage is high and the on-current is low is defined as data “0”, and a state in which the threshold voltage is low and the on-current is high is defined as data “1”, the memory cell MC can store 1-bit data of “0” and “1”.

The word lines WLa and WLb extend in the x direction. The word lines WLa and WLb are connected to gate electrodes of the memory cells MC. The word lines WLa and WLb each control a gate voltage of the memory cell MC.

The word line WLa and the word line WLb are electrically isolated from each other. The word lines WLa are electrically connected to each other. The word lines WLb are electrically connected to each other. Note that, in FIG. 2, two word lines WLa adjacent to each other in the y direction are actually formed by one conductive layer extending in the x direction. Similarly, in FIG. 2, two word lines WLb adjacent to each other in the y direction are actually formed by one conductive layer extending in the x direction.

The source selection transistor SST is electrically connected to the common source line CSL. The source selection transistor SST is controlled by a voltage applied to the source selection gate line SGS.

The drain selection transistors SDT are connected to BL1 to BL4. The drain selection transistor SDT is controlled by a voltage applied to the drain selection gate line SGD.

The plurality of word lines WLa and WLb are electrically connected to the word line driver circuit 102. The plurality of bit lines BL1 to BL4 are connected to the sense amplifier circuit 104.

The row decoder circuit 103 has a function of selecting the word line WLa or WLb according to an input row address signal. The word line driver circuit 102 has a function of applying a predetermined voltage to the word line WLa or WLb selected by the row decoder circuit 103.

The column decoder circuit 105 has a function of selecting the bit line BL according to an input column address signal. The sense amplifier circuit 104 has a function of applying a predetermined voltage to the bit line BL selected by the column decoder circuit 105. In addition, the sense amplifier circuit 104 has a function of sensing and amplifying a current or a voltage flowing through the selected bit line BL.

The control circuit 106 has a function of controlling the word line driver circuit 102, the row decoder circuit 103, the sense amplifier circuit 104, the column decoder circuit 105, and other circuits (not illustrated).

The circuits such as the word line driver circuit 102, the row decoder circuit 103, the sense amplifier circuit 104, and the column decoder circuit 105 include, for example, a transistor using a semiconductor layer (not illustrated) and a wiring layer.

For example, in FIG. 2, in a case where data stored in the selected memory cell MC surrounded by a broken line is read, a read voltage is applied to the word line WLa connected to the gate electrode of the selected memory cell MC. In addition, a path voltage is applied to the word line WLa connected to the gate electrode of the unselected memory cell MC other than the selected memory cell MC, the unselected memory cell MC being connected in series with the selected memory cell MC. The path voltage is, for example, a voltage higher than the read voltage. By applying the path voltage to the gate electrode, the transistor of the unselected memory cell MC is turned on. A current corresponding to a threshold voltage of the transistor of the selected memory cell MC flows between the common source line CSL and the bit line BL1. The data stored in the selected memory cell MC is determined based on the current flowing between the common source line CSL to the bit line BL1.

For example, the current flowing through the bit line BL1 is amplified by the sense amplifier circuit 104, and the control circuit 106 determines the data stored in the memory cell MC. Alternatively, a voltage change of the bit line BL1 is amplified by the sense amplifier circuit 104, and the control circuit 106 determines the data stored in the memory cell MC.

FIG. 2 illustrates a case where the number of memory cells MC connected in series is four and a case where the number of bit lines is four, but the number of memory cells MC connected in series and the number of bit lines are not limited to four.

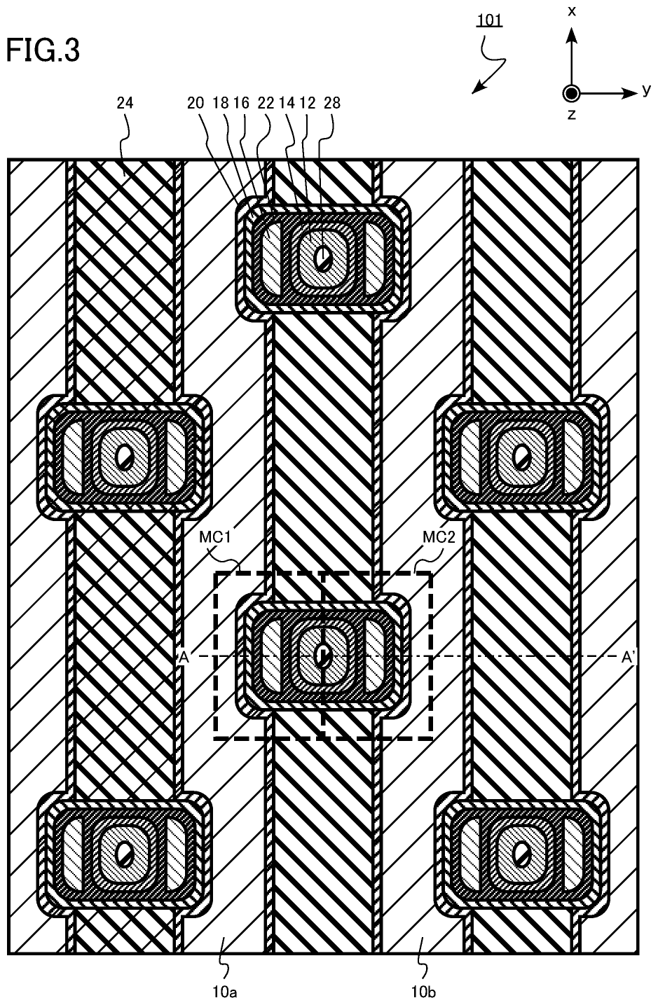

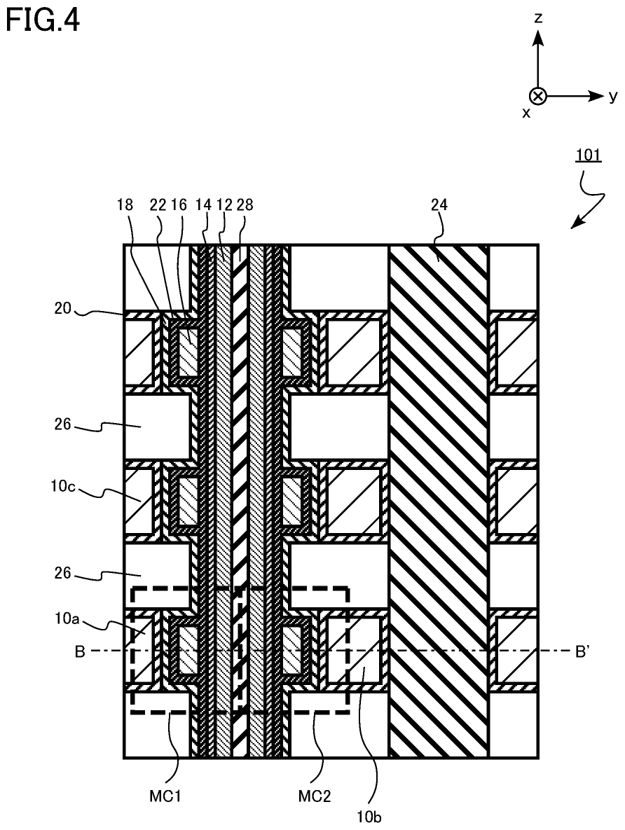

FIGS. 3 and 4 are schematic cross-sectional views of parts of the memory cell array of the semiconductor memory device according to the embodiment. FIG. 3 illustrates an xy cross section of the memory cell array 101. In FIG. 3, a cross section taken along B-B′ of FIG. 4 is included. FIG. 4 illustrates a yz cross section of the memory cell array 101. FIG. 4 illustrates a cross section taken along A-A′ of FIG. 3.

In FIGS. 3 and 4, a region surrounded by a broken line is one memory cell MC. FIGS. 3 and 4 illustrate a memory cell MC1 and a memory cell MC2 adjacent to each other in the y direction.

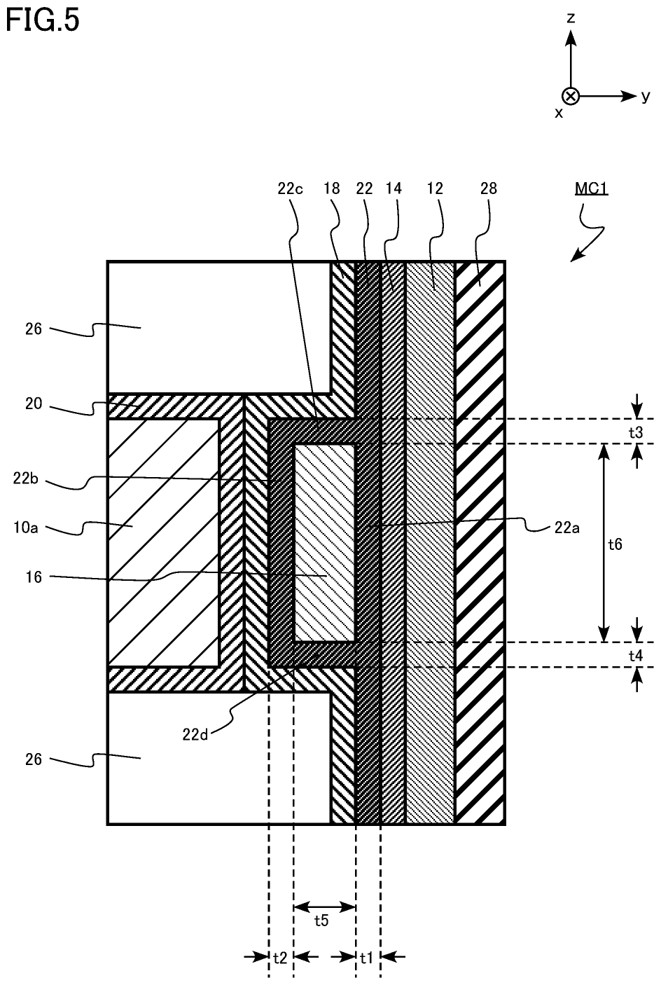

FIG. 5 is an enlarged schematic cross-sectional view of a part of the memory cell array of the semiconductor memory device according to the embodiment. FIG. 5 illustrates a yz cross section of the memory cell array 101. FIG. 5 illustrates a cross section of the memory cell MC1.

The memory cell array 101 includes a gate electrode layer 10, a semiconductor layer 12, a tunnel insulating layer 14, a charge storage layer 16, a first block insulating layer 18, a second block insulating layer 20, a barrier insulating layer 22, a trench insulating layer 24, an interlayer insulating layer 26, and a core insulating layer 28.

The gate electrode layer 10 includes a first gate electrode layer 10a, a second gate electrode layer 10b, and a third gate electrode layer 10c.

The tunnel insulating layer 14 is an example of a third insulating layer. The first block insulating layer 18 and the second block insulating layer 20 are examples of the first insulating layer. The barrier insulating layer 22 is an example of the second insulating layer. The interlayer insulating layer 26 is an example of a fourth insulating layer.

The gate electrode layer 10 extends in the x direction. A plurality of gate electrode layers 10 are repeatedly disposed in the y direction. The plurality of gate electrode layers 10 are repeatedly disposed in the z direction.

The gate electrode layer 10 is a conductive layer. The gate electrode layer 10 has, for example, a stacked structure of a barrier metal layer and a metal layer.

The barrier metal layer contains, for example, a metal nitride. The barrier metal layer contains, for example, titanium nitride. The barrier metal layer is, for example, titanium nitride.

The metal layer contains, for example, a metal. The metal layer contains, for example, tungsten (W). The metal layer is, for example, tungsten.

A thickness of the gate electrode layer 10 in the z direction is, for example, equal to or more than 10 nm and equal to or less than 30 nm.

The first gate electrode layer 10a extends in the x direction. The first gate electrode layer 10a corresponds to, for example, the word line WLa illustrated in FIG. 2. The first gate electrode layer 10a functions as a gate electrode of a transistor of the memory cell MC1.

The second gate electrode layer 10b extends in the x direction. The second gate electrode layer 10b is disposed in the y direction with respect to the first gate electrode layer 10a. The second gate electrode layer 10b is adjacent to the first gate electrode layer 10a in the y direction. The second gate electrode layer 10b corresponds to, for example, the word line WLb illustrated in FIG. 2. The second gate electrode layer 10b is electrically isolated from the first gate electrode layer 10a. The second gate electrode layer 10b functions as a gate electrode of a transistor of the memory cell MC2.

The third gate electrode layer 10c extends in the x direction. The third gate electrode layer 10c corresponds to, for example, the word line WLa illustrated in FIG. 2. The third gate electrode layer 10c is disposed in the z direction with respect to the first gate electrode layer 10a. The third gate electrode layer 10c is adjacent to the first gate electrode layer 10a in the z direction. The third gate electrode layer 10c is electrically isolated from the first gate electrode layer 10a. The interlayer insulating layer 26 is provided between the third gate electrode layer 10c and the first gate electrode layer 10a.

The semiconductor layer 12 extends in the z direction. The semiconductor layer 12 is provided in the y direction with respect to the gate electrode layer 10. The semiconductor layer 12 is provided, for example, between the first gate electrode layer 10a and the second gate electrode layer 10b. The semiconductor layer 12 has, for example, a cylindrical shape.

The semiconductor layer 12 functions as a channel of the transistor of the memory cell MC.

The semiconductor layer 12 is, for example, a polycrystalline semiconductor. The semiconductor layer 12 contains, for example, polycrystalline silicon. The semiconductor layer 12 is, for example, polycrystalline silicon. A thickness of the semiconductor layer 12 in an xy plane is, for example, equal to or more than 5 nm and equal to or less than 30 nm. A thickness of the semiconductor layer 12 in the y direction is, for example, equal to or more than 5 nm and equal to or less than 30 nm.

The tunnel insulating layer 14 is provided between the semiconductor layer 12 and the gate electrode layer 10. The tunnel insulating layer 14 surrounds the semiconductor layer 12, for example. The tunnel insulating layer 14 is provided between the semiconductor layer 12 and the charge storage layer 16. The tunnel insulating layer 14 is provided between the semiconductor layer 12 and the barrier insulating layer 22.

The tunnel insulating layer 14 functions as a charge transfer path between the semiconductor layer 12 and the charge storage layer 16 when writing data in the memory cell MC or erasing data from the memory cell MC. In addition, in a case where the memory cell MC is in a charge retention state, the tunnel insulating layer 14 functions to block transfer of charges between the semiconductor layer 12 and the charge storage layer 16.

The tunnel insulating layer 14 is an insulator. The tunnel insulating layer 14 contains, for example, an oxide, a nitride, or an oxynitride. The tunnel insulating layer 14 is, for example, an oxide, a nitride, or an oxynitride.

The tunnel insulating layer 14 contains, for example, silicon (Si) and oxygen (O). The tunnel insulating layer 14 contains, for example, silicon oxide. The tunnel insulating layer 14 is, for example, silicon oxide.

The tunnel insulating layer 14 contains, for example, silicon (Si), nitrogen (N), and oxygen (O). The tunnel insulating layer 14 contains, for example, silicon nitride or silicon oxynitride. The tunnel insulating layer 14 is, for example, silicon nitride or silicon oxynitride.

The tunnel insulating layer 14 has, for example, a stacked structure of silicon oxide and silicon nitride.

An atomic concentration of nitrogen of the tunnel insulating layer 14 is lower than an atomic concentration of nitrogen of the barrier insulating layer 22, for example.

A thickness of the tunnel insulating layer 14 in the y direction is, for example, equal to or more than 1 nm and equal to or less than 10 nm.

The charge storage layer 16 is provided between the semiconductor layer 12 and the gate electrode layer 10. The charge storage layer 16 is provided, for example, between the semiconductor layer 12 and the first gate electrode layer 10a. The charge storage layer 16 is provided, for example, between the tunnel insulating layer 14 and the first block insulating layer 18. The charge storage layer 16 is surrounded by the barrier insulating layer 22.

The charge storage layer 16 has a function of accumulating charges. Data is stored in the memory cell MC based on the charges accumulated in the charge storage layer 16.

The charge storage layer 16 is, for example, a paraelectric substance.

The charge storage layer 16 contains the first element, the second element, and oxygen (O). The first element is at least one element selected from the group consisting of hafnium (Hf) and zirconium (Zr). The second element is at least one element selected from the group consisting of nitrogen (N) and aluminum (Al). The charge storage layer 16 may contain both hafnium and zirconium as the first element. In addition, the charge storage layer 16 may contain both nitrogen and aluminum as the second element.

An atomic concentration of the first element of the charge storage layer is higher than an atomic concentration of the second element of the charge storage layer, for example. The charge storage layer 16 contains, for example, the first element and oxygen (O) as main component elements. The fact that the charge storage layer 16 contains the first element and oxygen (O) as main component elements means that there is no element having an atomic concentration higher than that of the first element or oxygen (O) among the elements contained in the charge storage layer 16.

The second element is an additive element. A ratio ((N+Al)/(N+Al+O)) of the atomic concentration of the second element to the sum of the atomic concentration of the second element and the atomic concentration of oxygen (O) in the charge storage layer 16 is, for example, equal to or more than 1.5% and equal to or less than 3.0%.

The charge storage layer 16 contains, for example, hafnium oxide. The charge storage layer 16 contains, for example, hafnium oxide as a main component. The fact that the charge storage layer 16 contains hafnium oxide as a main component means that a molar ratio of hafnium oxide is the highest among substances contained in the charge storage layer 16.

The charge storage layer 16 is, for example, hafnium oxide containing nitrogen (N) as an additive element. A ratio (N/(N+O)) of an atomic concentration of nitrogen (N) to the sum of the atomic concentration of nitrogen (N) and the atomic concentration of oxygen (O) in the charge storage layer 16 is, for example, equal to or more than 1.5% and equal to or less than 3.0%.

The charge storage layer 16 is, for example, hafnium oxide containing aluminum (Al) as an additive element. A ratio (Al/(Al+O)) of an atomic concentration of aluminum (Al) to the sum of the atomic concentration of aluminum (Al) and the atomic concentration of oxygen (O) in the charge storage layer 16 is, for example, equal to or more than 1.5% or more and equal to or less than 3.0%.

The charge storage layer 16 contains, for example, zirconium oxide. The charge storage layer 16 contains, for example, zirconium oxide as a main component. The fact that the charge storage layer 16 contains zirconium oxide as a main component means that a molar ratio of zirconium oxide is the highest among the substances contained in the charge storage layer 16.

The charge storage layer 16 is, for example, zirconium oxide containing nitrogen (N) as an additive element. A ratio (N/(N+O)) of an atomic concentration of nitrogen (N) to the sum of the atomic concentration of nitrogen (N) and the atomic concentration of oxygen (O) in the charge storage layer 16 is, for example, equal to or more than 1.5% and equal to or less than 3.0%.

The charge storage layer 16 is, for example, zirconium oxide containing aluminum (Al) as an additive element. A ratio (Al/(Al+O)) of an atomic concentration of aluminum (Al) to the sum of the atomic concentration of aluminum (Al) and the atomic concentration of oxygen (O) in the charge storage layer 16 is, for example, equal to or more than 1.5% or more and equal to or less than 3.0%.

A thickness of the charge storage layer 16 in the y direction is larger than the thickness of the tunnel insulating layer 14 in the y direction, for example. The thickness of the charge storage layer 16 in the y direction is, for example, equal to or more than 2 nm and equal to or less than 10 nm.

The first block insulating layer 18 is provided between the charge storage layer 16 and the gate electrode layer 10. The first block insulating layer 18 is provided, for example, between the charge storage layer 16 and the first gate electrode layer 10a. The first block insulating layer 18 is provided between the barrier insulating layer 22 and the second block insulating layer 20.

The first block insulating layer 18 has a function of blocking transfer of charges between the gate electrode layer 10 and the charge storage layer 16.

The first block insulating layer 18 is an insulator. The first block insulating layer 18 contains, for example, an oxide, a nitride, or an oxynitride. The first block insulating layer 18 is, for example, an oxide, a nitride, or an oxynitride.

The first block insulating layer 18 contains, for example, silicon (Si) and oxygen (O). The first block insulating layer 18 includes, for example, silicon oxide. The first block insulating layer 18 is, for example, silicon oxide.

A thickness of the first block insulating layer 18 in the y direction is larger than the thickness of the tunnel insulating layer 14 in the y direction, for example. The thickness of the first block insulating layer 18 in the y direction is, for example, equal to or more than 3 nm and equal to or less than 10 nm.

The second block insulating layer 20 is provided between the charge storage layer 16 and the gate electrode layer 10. The second block insulating layer 20 is provided, for example, between the charge storage layer 16 and the first gate electrode layer 10a. The second block insulating layer 20 is provided between the first block insulating layer 18 and the gate electrode layer 10.

The second block insulating layer 20 has a function of blocking transfer of charges between the gate electrode layer 10 and the charge storage layer 16.

The second block insulating layer 20 is an insulator. The second block insulating layer 20 contains, for example, an oxide, a nitride, or an oxynitride. The second block insulating layer 20 is, for example, an oxide, a nitride, or an oxynitride. The second block insulating layer 20 is formed of, for example, a material different from that of the first block insulating layer 18.

The second block insulating layer 20 contains aluminum (Al) and oxygen (O). The second block insulating layer 20 contains, for example, aluminum oxide. The second block insulating layer 20 is, for example, aluminum oxide.

A thickness of the second block insulating layer 20 in the y direction is larger than the thickness of the tunnel insulating layer 14 in the y direction, for example. The thickness of the second block insulating layer 20 in the y direction is, for example, equal to or more than 3 nm and equal to or less than 10 nm.

The barrier insulating layer 22 is provided between the semiconductor layer 12 and the gate electrode layer 10. The barrier insulating layer 22 is provided between the tunnel insulating layer 14 and the first block insulating layer 18. The barrier insulating layer 22 has a function of preventing diffusion of the second element contained in the charge storage layer 16. The barrier insulating layer 22 has a function of preventing diffusion of the additive element contained in the charge storage layer 16. The barrier insulating layer 22 has a function of preventing diffusion of nitrogen (N) or aluminum (Al) contained in the charge storage layer 16.

The barrier insulating layer 22 is provided, for example, between the semiconductor layer 12 and the interlayer insulating layer 26.

The barrier insulating layer 22 has a first region 22a, a second region 22b, a third region 22c, and a fourth region 22d. For example, the first region 22a, the second region 22b, the third region 22c, and the fourth region 22d are continuous.

The first region 22a is provided between the semiconductor layer 12 and the charge storage layer 16. The first region 22a is provided between the tunnel insulating layer 14 and the charge storage layer 16. The second region 22b is provided between the charge storage layer 16 and the first block insulating layer 18. The charge storage layer 16 is provided between the first region 22a and the second region 22b. The charge storage layer 16 is interposed between the first region 22a and the second region 22b in the y direction.

The first region 22a is in contact with, for example, the tunnel insulating layer 14. The second region 22b is in contact with, for example, the first block insulating layer 18.

The third region 22c is provided between the charge storage layer 16 and the interlayer insulating layer 26. The fourth region 22d is provided between the charge storage layer 16 and the interlayer insulating layer 26. The charge storage layer 16 is provided between the third region 22c and the fourth region 22d. The charge storage layer 16 is interposed between the third region 22c and the fourth region 22d in the z direction.

The barrier insulating layer 22 surrounds the charge storage layer 16 in a cross section, the cross section being parallel to the z direction and including the charge storage layer 16. For example, as illustrated in FIGS. 4 and 5, the barrier insulating layer 22 surrounds the charge storage layer 16 in the yz cross section including the charge storage layer 16. The barrier insulating layer 22 is in contact with the charge storage layer 16 in the y direction and the z direction.

The barrier insulating layer 22 surrounds the charge storage layer 16, for example, in a cross section, the cross section intersecting the z direction and including the charge storage layer 16. For example, as illustrated in FIG. 3, the barrier insulating layer 22 surrounds the charge storage layer 16 in the xy plane, the xy plane being orthogonal to the z direction and including the charge storage layer 16. The barrier insulating layer 22 is in contact with the charge storage layer 16 in the x direction and the y direction.

The barrier insulating layer 22 contains silicon (Si) and nitrogen (N). The barrier insulating layer 22 contains, for example, silicon (Si) and nitrogen (N) as main component elements. The fact that the barrier insulating layer 22 contains silicon (Si) and nitrogen (N) as main component elements means that there is no element having an atomic concentration higher than that of silicon (Si) or nitrogen (N) among the elements contained in the barrier insulating layer 22.

The barrier insulating layer 22 contains, for example, silicon nitride. The barrier insulating layer 22 contains, for example, silicon nitride as a main component. The fact that the barrier insulating layer 22 contains silicon nitride as a main component means that a molar ratio of silicon nitride is the highest among substances contained in the barrier insulating layer 22. The barrier insulating layer 22 is, for example, silicon nitride.

A material of the barrier insulating layer 22 is different from, for example, materials of the tunnel insulating layer 14 and the first block insulating layer 18. The material of the barrier insulating layer 22 is different from a material of the charge storage layer 16.

The atomic concentration of nitrogen of the barrier insulating layer 22 is higher than the atomic concentration of nitrogen of the tunnel insulating layer 14, for example. The atomic concentration of nitrogen of the barrier insulating layer 22 is higher than an atomic concentration of nitrogen of the first block insulating layer 18, for example. The atomic concentration of nitrogen of the barrier insulating layer 22 is higher than an atomic concentration of nitrogen of the charge storage layer 16, for example.

The barrier insulating layer 22 contains, for example, silicon (Si), nitrogen (N), and oxygen (O). The barrier insulating layer 22 contains, for example, silicon oxynitride. The barrier insulating layer 22 is, for example, silicon oxynitride.

A thickness (t1 in FIG. 5) of the first region 22a of the barrier insulating layer 22 in the y direction is, for example, smaller than the thickness (t5 in FIG. 5) of the charge storage layer 16 in the y direction. The thickness t1 of the first region 22a in the y direction is, for example, equal to or more than 0.5 nm and equal to or less than 3 nm.

A thickness (t2 in FIG. 5) of the second region 22b of the barrier insulating layer 22 in the y direction is, for example, smaller than the thickness (t5 in FIG. 5) of the charge storage layer 16 in the y direction. The thickness t2 of the second region 22b in the y direction is, for example, equal to or more than 0.5 nm and equal to or less than 3 nm.

A thickness (t3 in FIG. 5) of the third region 22c of the barrier insulating layer 22 in the z direction is, for example, smaller than a thickness (t6 in FIG. 5) of the charge storage layer 16 in the z direction. The thickness t3 of the third region 22c in the z direction is, for example, equal to or more than 0.5 nm and equal to or less than 3 nm.

A thickness (t4 in FIG. 5) of the fourth region 22d of the barrier insulating layer 22 in the z direction is, for example, smaller than the thickness (t6 in FIG. 5) of the charge storage layer 16 in the z direction. The thickness t4 of the fourth region 22d in the z direction is, for example, equal to or more than 0.5 nm and equal to or less than 3 nm.

The trench insulating layer 24 contains, for example, silicon (Si) and oxygen (O). The trench insulating layer 24 contains, for example, silicon oxide. The trench insulating layer 24 is, for example, silicon oxide.

The trench insulating layer 24 is provided between the gate electrode layers 10 adjacent to each other in the y direction. For example, the trench insulating layer 24 is provided between the first gate electrode layer 10a and the second gate electrode layer 10b.

The trench insulating layer 24 is, for example, an oxide, an oxynitride, or a nitride. The trench insulating layer 24 contains, for example, silicon oxide or aluminum oxide. The trench insulating layer 24 is, for example, silicon oxide or aluminum oxide.

The interlayer insulating layers 26 are arranged in the z direction. The interlayer insulating layer 26 is provided between the gate electrode layers 10 adjacent to each other in the z direction. The gate electrode layer 10 is interposed between two interlayer insulating layers 26 in the z direction. For example, as illustrated in FIG. 4, the interlayer insulating layer 26 is provided between the first gate electrode layer 10a and the third gate electrode layer 10c.

The interlayer insulating layer 26 is, for example, an oxide, an oxynitride, or a nitride. The interlayer insulating layer 26 contains, for example, silicon (Si) and oxygen (O). The interlayer insulating layer 26 contains, for example, silicon oxide. The interlayer insulating layer 26 is, for example, silicon oxide. A thickness of the interlayer insulating layer 26 in the z direction is, for example, equal to or more than 5 nm and equal to or less than 30 nm.

The core insulating layer 28 is surrounded by the semiconductor layer 12. The core insulating layer 28 extends in the z direction. The core insulating layer 28 has, for example, a cylindrical shape.

The core insulating layer 28 is, for example, an oxide, an oxynitride, or a nitride. The core insulating layer 28 contains, for example, silicon oxide. The core insulating layer 28 is, for example, silicon oxide.

Next, an example of a method for manufacturing the semiconductor memory device according to the embodiment will be described.

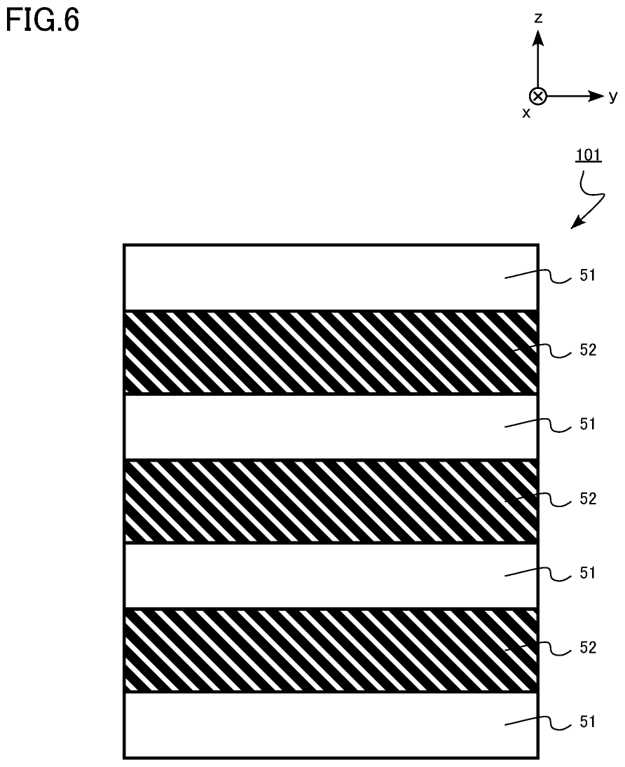

FIGS. 6, 7, 8, 9, 10, 11, 12, 13, 14, 15, 16, 17, 18, 19, 20, and 21 are schematic cross-sectional views illustrating the method for manufacturing the semiconductor memory device according to the embodiment. FIGS. 6 to 21 are diagrams illustrating an example of a method for manufacturing the memory cell array 101 of the three-dimensional NAND flash memory 100.

FIGS. 6 to 21 correspond to the yz cross section of the memory cell array 101.

First, a first silicon oxide film 51 and a first silicon nitride film 52 are alternately and repeatedly stacked on a semiconductor substrate (not illustrated) (FIG. 6).

The first silicon oxide film 51 and the first silicon nitride film 52 are formed by, for example, a chemical vapor deposition method (CVD method). A part of the first silicon oxide film 51 finally becomes the interlayer insulating layer 26.

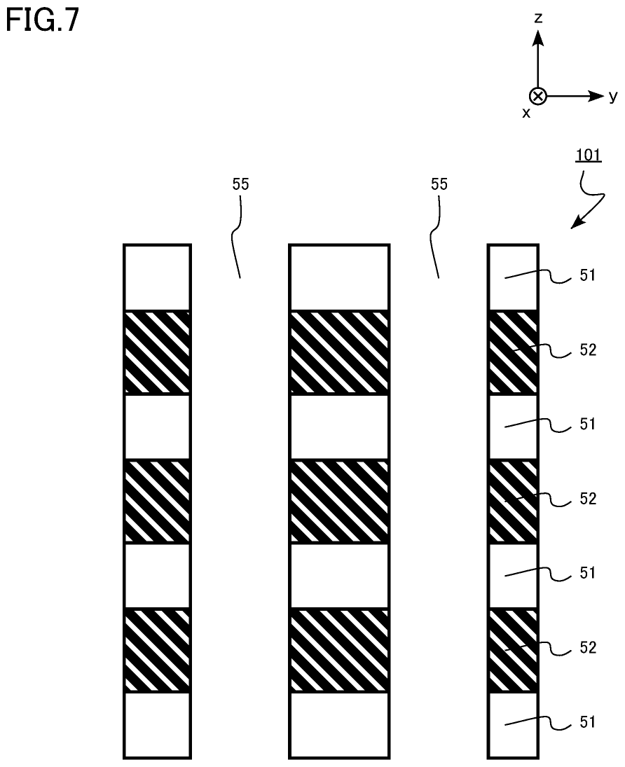

Next, a memory trench 55 is formed in the first silicon oxide film 51 and the first silicon nitride film 52 (FIG. 7). The memory trench 55 penetrates through the first silicon oxide film 51 and the first silicon nitride film 52.

The memory trench 55 is formed by, for example, a lithography method and a reactive ion etching method (RIE method).

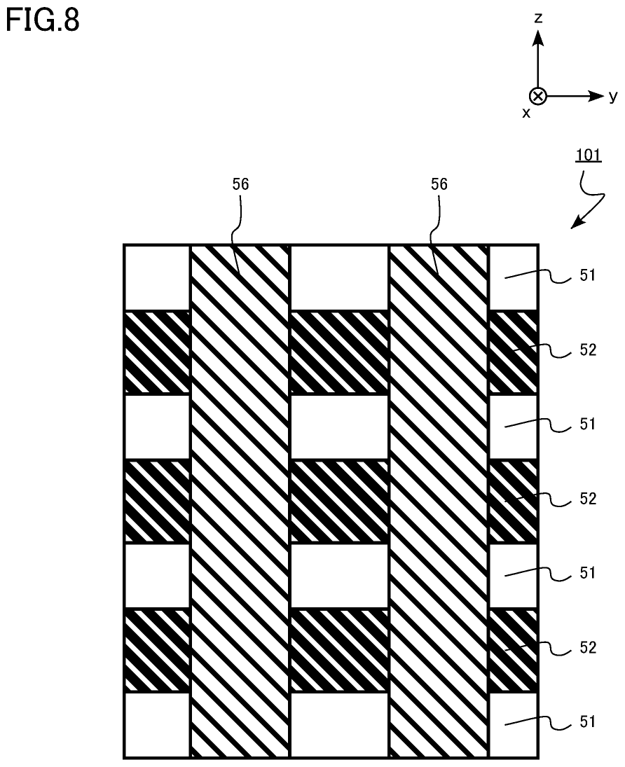

Next, the memory trench 55 is filled with a second silicon oxide film 56 (FIG. 8). The second silicon oxide film 56 is formed by, for example, the CVD method. The second silicon oxide film 56 finally becomes the trench insulating layer 24.

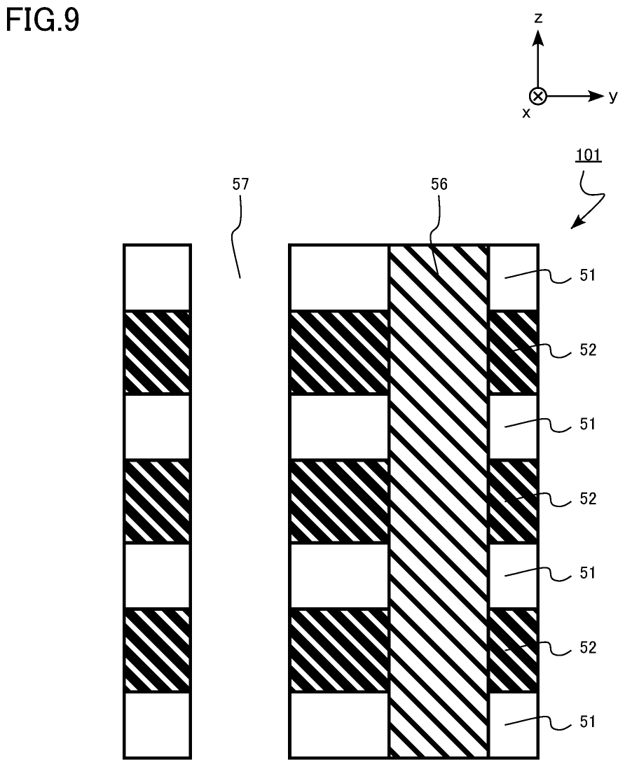

Next, a memory hole 57 penetrating through the second silicon oxide film 56, the first silicon oxide film 51, and the first silicon nitride film 52 is formed (FIG. 9). The memory hole 57 is formed by, for example, the lithography method and the RIE method.

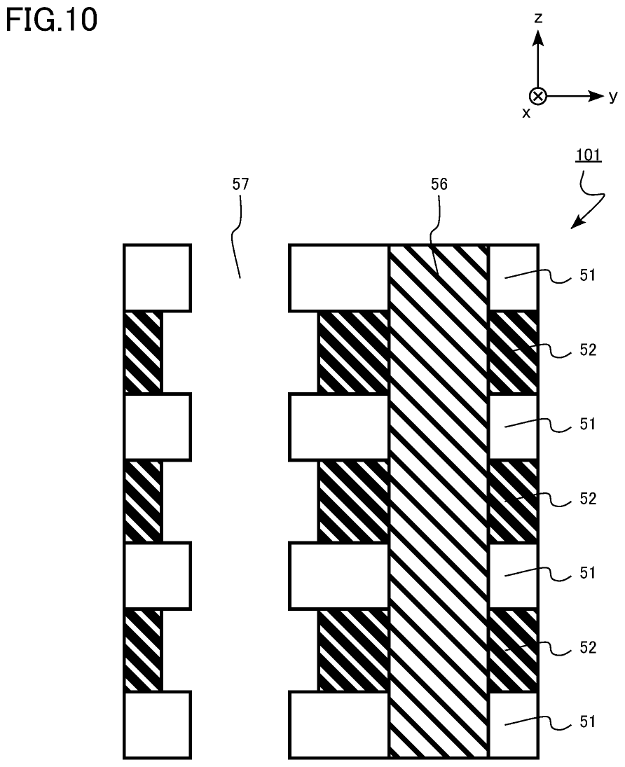

Next, a part of the first silicon nitride film 52 exposed on an inner face of the memory hole 57 is selectively removed with respect to the first silicon oxide film 51 (FIG. 10). The first silicon nitride film 52 is retracted in the y direction. The first silicon nitride film 52 is removed by, for example, a wet etching method. The first silicon nitride film 52 is etched using, for example, a phosphoric acid solution.

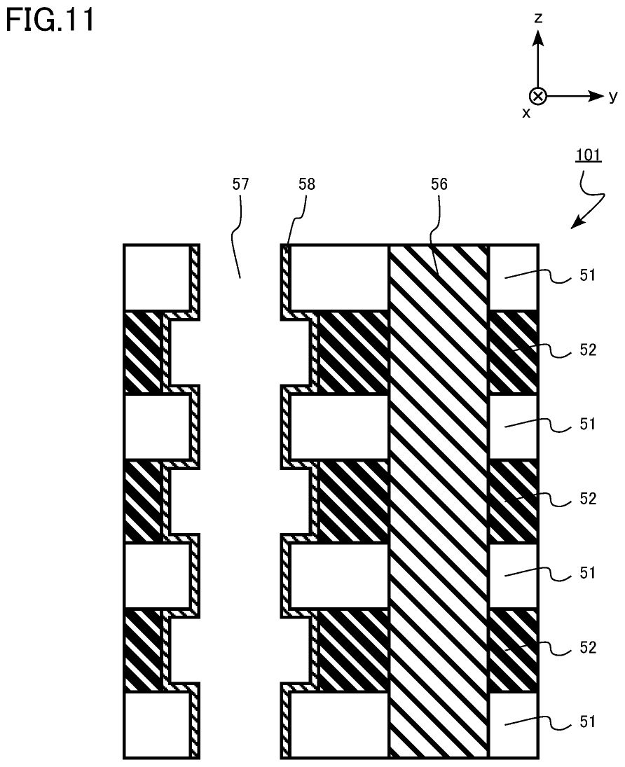

Next, a third silicon oxide film 58 is formed in the memory hole 57 (FIG. 11). The third silicon oxide film 58 is formed by, for example, the CVD method. In addition, the third silicon oxide film 58 may be formed by, for example, thermally oxidizing a silicon nitride film formed by the CVD method. The third silicon oxide film 58 finally becomes the first block insulating layer 18.

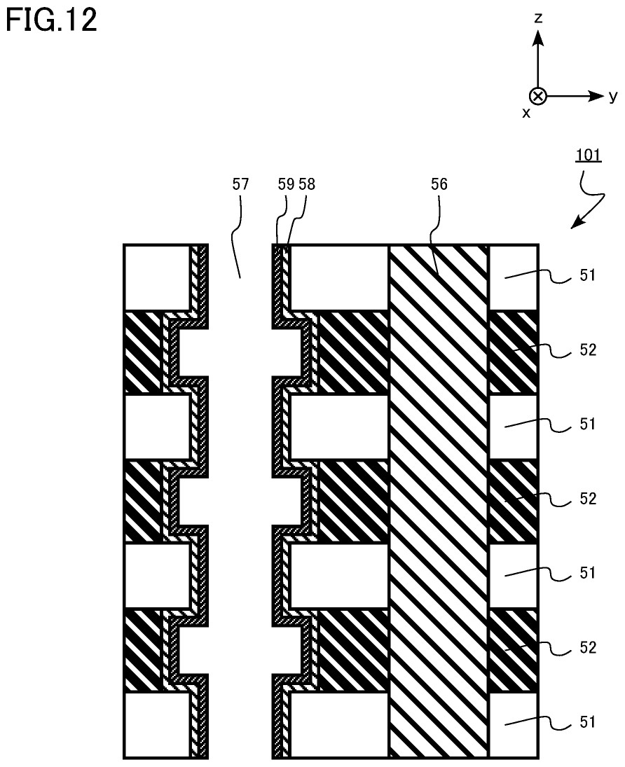

Next, a second silicon nitride film 59 is formed on the third silicon oxide film 58 on the inner face of the memory hole 57 (FIG. 12). The second silicon nitride film 59 is formed by, for example, the CVD method. The second silicon nitride film 59 finally becomes a part of the barrier insulating layer 22.

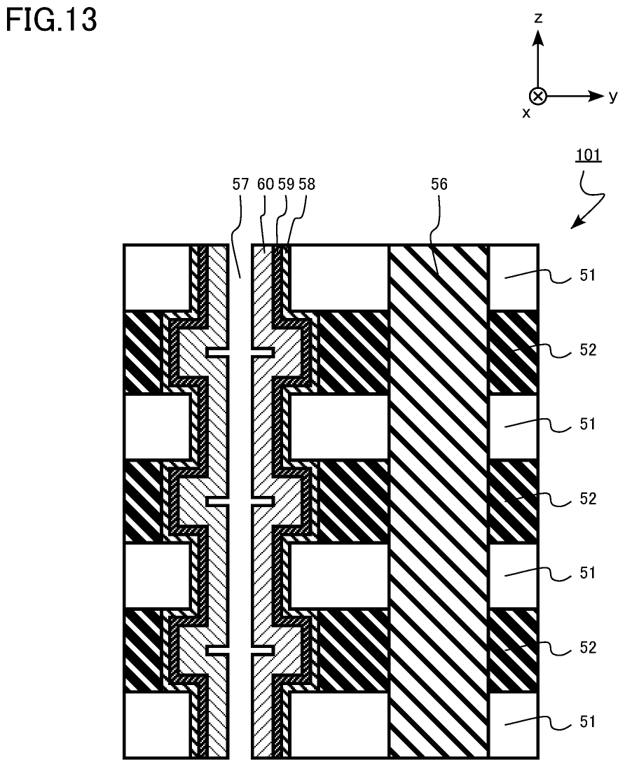

Next, a hafnium oxide film 60 containing nitrogen is formed on the second silicon nitride film 59 on the inner face of the memory hole 57 (FIG. 13). The hafnium oxide film 60 is formed by, for example, an atomic layer deposition method (ALD method). A part of the hafnium oxide film 60 finally becomes the charge storage layer 16.

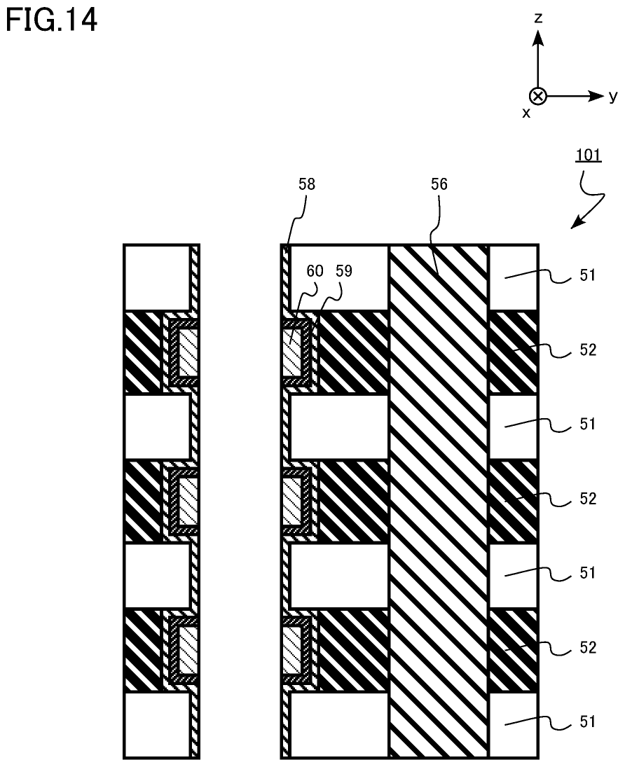

Next, a part of the hafnium oxide film 60 and a part of the second silicon nitride film 59 on the inner face of the memory hole 57 are removed (FIG. 14). The hafnium oxide film 60 and the second silicon nitride film 59 are removed by, for example, the RIE method. The hafnium oxide film 60 and the second silicon nitride film 59 remain in a recessed portion of the third silicon oxide film 58.

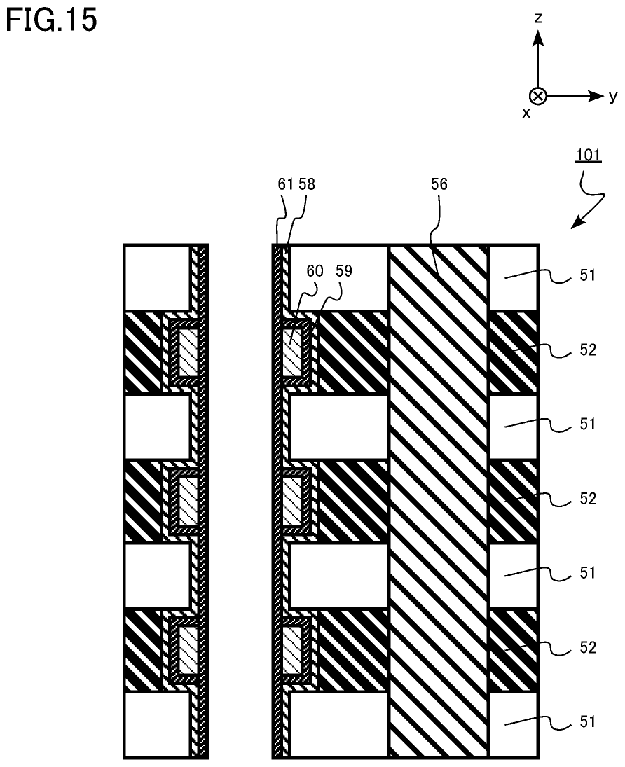

Next, a third silicon nitride film 61 is formed on the hafnium oxide film 60 in the memory hole 57 (FIG. 15). The third silicon nitride film 61 is formed by, for example, the CVD method. The third silicon nitride film 61 is in contact with the second silicon nitride film 59. The third silicon nitride film 61 finally becomes a part of the barrier insulating layer 22.

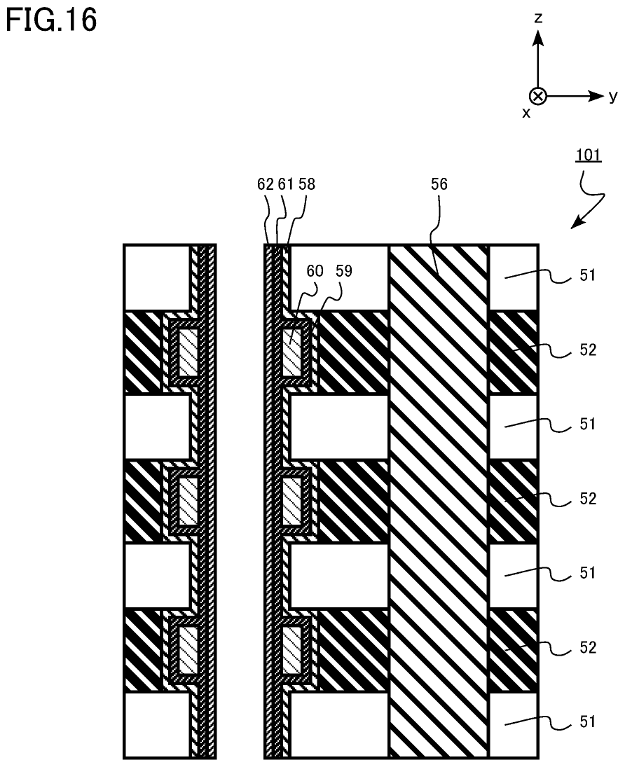

Next, a fourth silicon oxide film 62 is formed on the third silicon nitride film 61 in the memory hole 57 (FIG. 16). The fourth silicon oxide film 62 is formed by, for example, the CVD method. The fourth silicon oxide film 62 finally becomes the tunnel insulating layer 14.

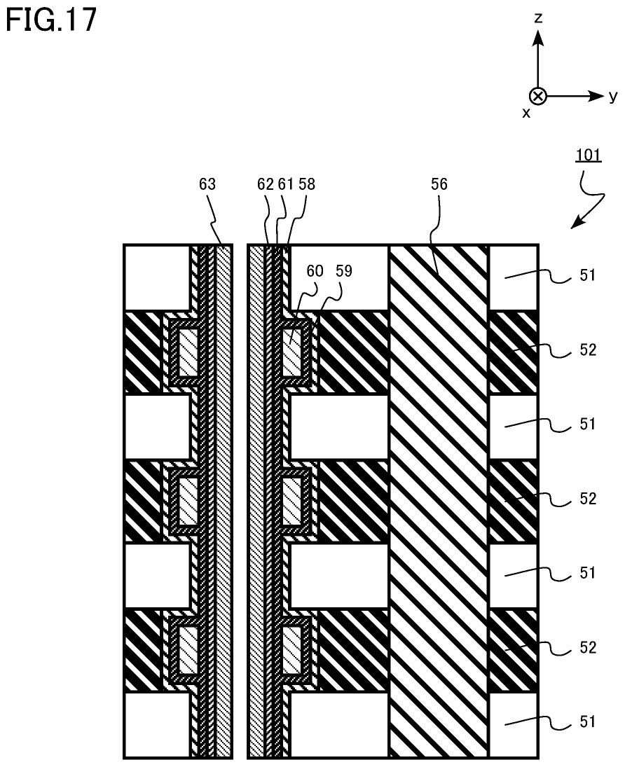

Next, a polycrystalline silicon film 63 is formed on the fourth silicon oxide film 62 on the inner face of the memory hole 57 (FIG. 17). The polycrystalline silicon film 63 is formed by, for example, the CVD method. The polycrystalline silicon film 63 finally becomes the semiconductor layer 12.

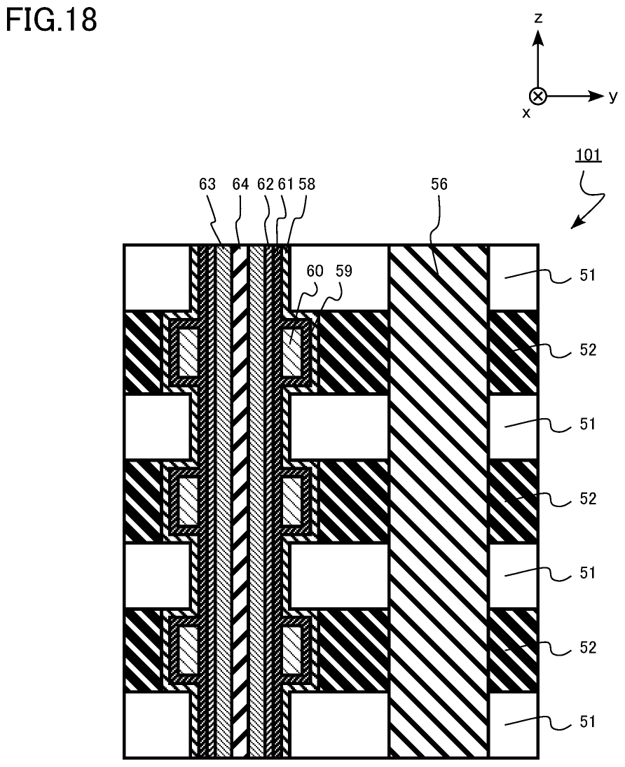

Next, the memory hole 57 is filled with a fifth silicon oxide film 64 (FIG. 18). The fifth silicon oxide film 64 is formed by, for example, the CVD method. The fifth silicon oxide film 64 finally becomes the core insulating layer 28.

Next, a slit trench (not illustrated) is formed in the first silicon oxide film 51 and the first silicon nitride film 52. The slit trench penetrates through the first silicon oxide film 51 and the first silicon nitride film 52. Note that the slit trench is provided at an end portion of the memory cell array 101.

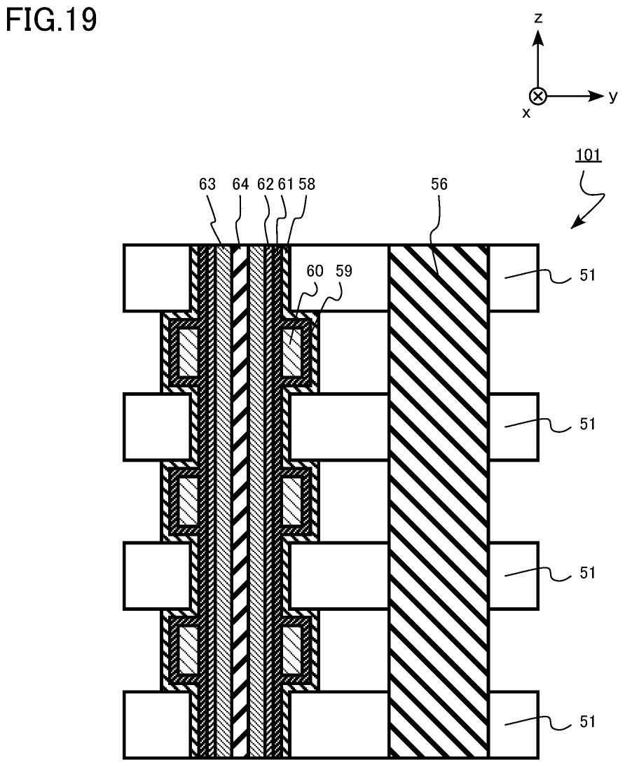

Next, the first silicon nitride film 52 is selectively removed with respect to the first silicon oxide film 51 via the slit trench (FIG. 19). The first silicon nitride film 52 is removed by, for example, a wet etching method. The first silicon nitride film 52 is etched using, for example, a phosphoric acid solution.

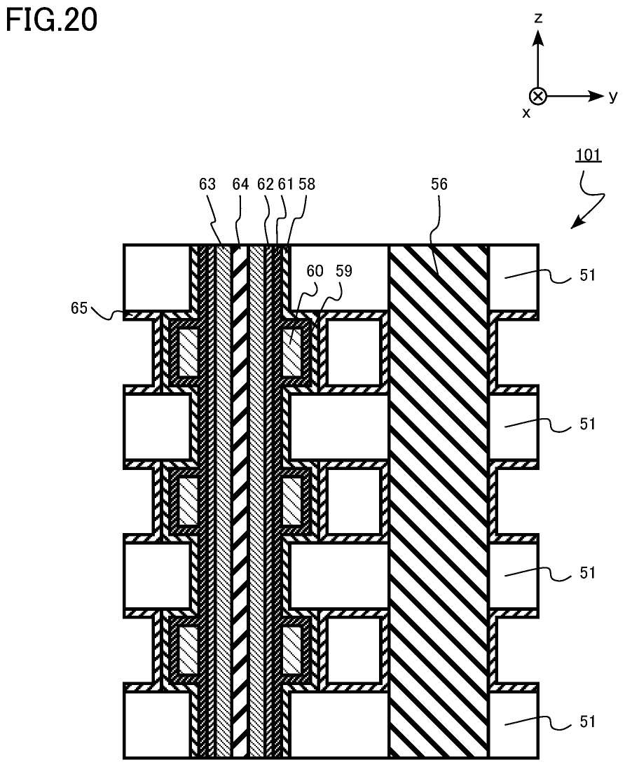

Next, an aluminum oxide film 65 is formed at a portion from which the first silicon nitride film 52 has been removed (FIG. 20). The aluminum oxide film 65 is formed by, for example, the CVD method. The aluminum oxide film 65 finally becomes the second block insulating layer 20. After the aluminum oxide film 65 is formed, for example, crystallization annealing for crystallizing the aluminum oxide film 65 is performed at a temperature of equal to or higher than 1000° C.

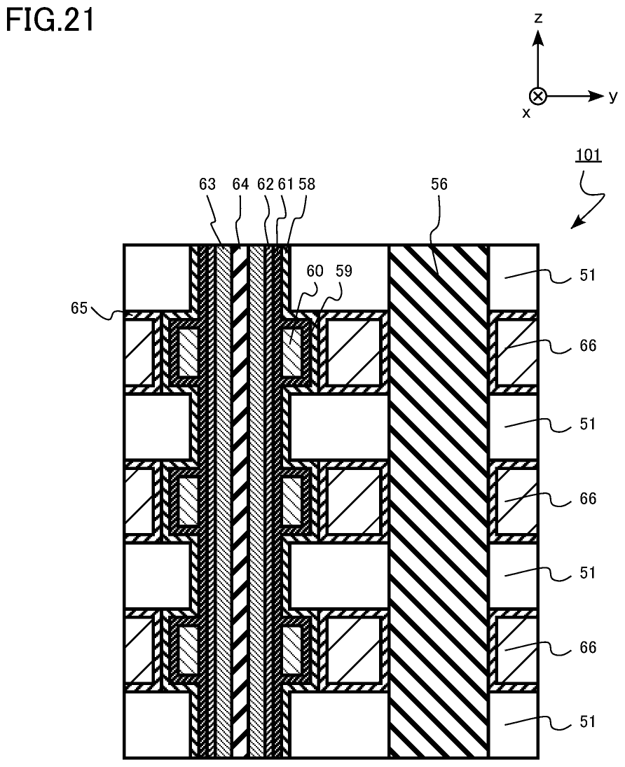

Next, a stacked film 66 of a titanium film and a tungsten film is formed on the aluminum oxide film 65 (FIG. 21). The stacked film 66 is formed by, for example, the CVD method. The stacked film 66 finally becomes the gate electrode layer 10.

The memory cell array 101 of the three-dimensional NAND flash memory 100 according to the embodiment is manufactured by the above manufacturing method.

Next, functions and effects of the semiconductor memory device according to the embodiment will be described.

A three-dimensional NAND flash memory in which memory cells are three-dimensionally disposed implements a high degree of integration and a low cost. A memory cell of the three-dimensional NAND flash memory includes a charge storage layer for retention of charges. The three-dimensional NAND flash memory is required to have an excellent charge retention characteristic.

The three-dimensional NAND flash memory 100 according to the embodiment can implement an excellent charge retention characteristic by applying hafnium oxide or zirconium oxide containing nitrogen or aluminum as an additive element to the charge storage layer 16.

On the other hand, in a case where hafnium oxide or zirconium oxide containing nitrogen or aluminum as an additive element is applied to the charge storage layer, there is a concern that the additive element contained in the charge storage layer is diffused and the charge retention characteristic is degraded. There is a possibility that the charge retention characteristic is degraded due to a decrease of the amount of additive element in the charge storage layer. For example, there is a concern that diffusion of the additive element occurs during high-temperature annealing such as crystallization annealing of an aluminum oxide film.

The three-dimensional NAND flash memory 100 according to the embodiment includes the barrier insulating layer 22 surrounding the charge storage layer 16. The barrier insulating layer 22 contains silicon (Si) and nitrogen (N). The barrier insulating layer 22 is, for example, silicon nitride.

The barrier insulating layer 22 completely surrounds the charge storage layer 16, thereby suppressing diffusion of the additive element from the charge storage layer 16 and a decrease of the amount of additive element in the charge storage layer 16. Therefore, degradation of the charge retention characteristic is suppressed, and the three-dimensional NAND flash memory 100 that implements the excellent charge retention characteristic can be implemented.

From the viewpoint of increasing a charge accumulation amount of the charge storage layer 16 and implementing an excellent charge retention characteristic, the ratio ((N+Al)/(N+Al+O)) of the atomic concentration of the additive element to the sum of the atomic concentration of the additive element and the atomic concentration of oxygen (O) in the charge storage layer 16 is preferably equal to or more than 1.5% and equal to or less than 3.0%.

In a case where the additive element is nitrogen (N), from the viewpoint of increasing the charge accumulation amount of the charge storage layer 16 and implementing an excellent charge retention characteristic, the ratio (N/(N+O)) of the atomic concentration of nitrogen (N) to the sum of the atomic concentration of nitrogen (N) and the atomic concentration of oxygen (O) in the charge storage layer 16 is preferably equal to or more than 1.5% and equal to or less than 3.0%.

In a case where the additive element is aluminum (Al), from the viewpoint of increasing the charge accumulation amount of the charge storage layer 16 and implementing an excellent charge retention characteristic, the ratio (Al/(Al+O)) of the atomic concentration of aluminum (Al) to the sum of the atomic concentration of aluminum (Al) and the atomic concentration of oxygen (O) in the charge storage layer 16 is preferably equal to or more than 1.5% and equal to or less than 3.0%.

From the viewpoint of improving the effect of preventing diffusion of the additive element by the barrier insulating layer 22, the atomic concentration of nitrogen of the barrier insulating layer 22 is preferably high. Therefore, the atomic concentration of nitrogen of the barrier insulating layer 22 is preferably higher than the atomic concentration of nitrogen in the tunnel insulating layer 14. The atomic concentration of nitrogen of the barrier insulating layer 22 is preferably higher than the atomic concentration of nitrogen of the first block insulating layer 18. The atomic concentration of nitrogen of the barrier insulating layer 22 is preferably higher than the atomic concentration of nitrogen of the charge storage layer 16.

In the embodiment, the memory cell array structure in which the semiconductor layer 12 functioning as a channel is provided between two electrically isolated gate electrode layers 10 has been described as an example. However, the memory cell array structure of the three-dimensional NAND flash memory is not limited to the memory cell array structure according to the embodiment. For example, it is also possible to adopt a memory cell array structure in which a semiconductor layer functioning as a channel penetrates through a plate-shaped gate electrode layer and is surrounded by the gate electrode layer.

While certain embodiments have been described, these embodiments have been presented by way of example only, and are not intended to limit the scope of the inventions. Indeed, the semiconductor memory device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a semiconductor layer extending in a first direction;
a first gate electrode layer;
a charge storage layer provided between the semiconductor layer and the first gate electrode layer, the charge storage layer containing a first element, a second element, and oxygen (O), the first element being at least one element selected from the group consisting of hafnium (Hf) and zirconium (Zr), and the second element being at least one element selected from the group consisting of nitrogen (N) and aluminum (Al);
a first insulating layer provided between the charge storage layer and the first gate electrode layer; and
a second insulating layer provided between the semiconductor layer and the first gate electrode layer, the second insulating layer containing silicon (Si) and nitrogen (N), the second insulating layer surrounding the charge storage layer in a cross section, and the cross section being parallel to the first direction and including the charge storage layer.

2. The semiconductor memory device according to claim 1, wherein the second insulating layer surrounds the charge storage layer in a cross section intersecting the first direction and including the charge storage layer.

3. The semiconductor memory device according to claim 1, wherein the second insulating layer includes a first region and a second region, the first region is provided between the semiconductor layer and the charge storage layer, and the second region is provided between the charge storage layer and the first insulating layer.

4. The semiconductor memory device according to claim 1, wherein the second insulating layer is in contact with the charge storage layer.

5. The semiconductor memory device according to claim 1, wherein an atomic concentration of the first element in the charge storage layer is higher than an atomic concentration of the second element in the charge storage layer.

6. The semiconductor memory device according to claim 1, wherein a ratio ((N+Al)/(N+Al+O)) of an atomic concentration of the second element to a sum of the atomic concentration of the second element and an atomic concentration of oxygen (O) in the charge storage layer is equal to or more than 1.5% and equal to or less than 3.0%.

7. The semiconductor memory device according to claim 1, wherein a ratio (N/(N+O)) of an atomic concentration of nitrogen (N) to a sum of the atomic concentration of nitrogen (N) and an atomic concentration of oxygen (O) in the charge storage layer is equal to or more than 1.5% and equal to or less than 3.0%.

8. The semiconductor memory device according to claim 1, wherein a ratio (Al/(Al+O)) of an atomic concentration of aluminum (Al) to a sum of the atomic concentration of aluminum (Al) and an atomic concentration of oxygen (O) in the charge storage layer is equal to or more than 1.5% and equal to or less than 3.0%.

9. The semiconductor memory device according to claim 1, wherein the second insulating layer contains oxygen (O).

10. The semiconductor memory device according to claim 1, further comprising a third insulating layer provided between the semiconductor layer and the second insulating layer, and the third insulating layer having an atomic concentration of nitrogen lower than an atomic concentration of nitrogen in the second insulating layer.

11. The semiconductor memory device according to claim 10, wherein the second insulating layer is in contact with the third insulating layer.

12. The semiconductor memory device according to claim 1, further comprising a second gate electrode layer,
wherein the first gate electrode layer extends in a second direction intersecting the first direction, the second gate electrode layer is disposed in a third direction with respect to the first gate electrode layer, the third direction intersecting the first direction and the second direction, the second gate electrode layer extends in the second direction, and the semiconductor layer is provided between the first gate electrode layer and the second gate electrode layer.

13. The semiconductor memory device according to claim 1, further comprising:
a third gate electrode layer disposed in the first direction with respect to the first gate electrode layer; and
a fourth insulating layer provided between the first gate electrode layer and the third gate electrode layer.

14. The semiconductor memory device according to claim 13, wherein the second insulating layer includes a third region, and the third region is provided between the charge storage layer and the fourth insulating layer.

15. The semiconductor memory device according to claim 14, wherein a thickness of the third region in the first direction is smaller than a thickness of the charge storage layer in the first direction.

16. The semiconductor memory device according to claim 1, wherein the first insulating layer contains silicon (Si), aluminum (Al), and oxygen (O).

17. The semiconductor memory device according to claim 1, wherein the second insulating layer includes a first region, the first region is provided between the semiconductor layer and the charge storage layer, and a thickness of the first region in a third direction from the semiconductor layer toward the charge storage layer is smaller than a thickness of the charge storage layer in the third direction.

18. The semiconductor memory device according to claim 1, wherein the second insulating layer includes a second region, the second region is provided between the charge storage layer and the first insulating layer, and a thickness of the second region in a third direction from the charge storage layer toward the first insulating layer is smaller than a thickness of the charge storage layer in the third direction.
